(19) United States
(12) Patent Application Publication
(10) Pub. No.: US 2022/0095469 A1
(43) Pub. Date: Mar. 24, 2022

(54) COMPOSITE STRUCTURE AND METHOD OF MAKING THE SAME

(71) Applicant: GIANT GLORY INTERNATIONAL LIMITED, Apia (WS)

(72) Inventors: Hsiang-Jui WANG, Taoyuan City (TW); Shun-Jie YANG, New Taipei City (TW); Cheng-Ping HSIAO, Changzhi Township (TW)

(21) Appl. No.: 17/104,506

(22) Filed: Nov. 25, 2020

(30) Foreign Application Priority Data
Sep. 24, 2020 (TW) 109133109

(51) Int. Cl. H05K 5/04; B22D 17/00; C25D 11/30; C25D 13/20

(52) U.S. Cl. CPC H05K 5/04; C25D 13/20; C25D 11/30; B22D 17/00

(57) ABSTRACT

A composite structure includes a passivated substrate, a sealing layer, a conductive layer, and a coating layer. The passivated substrate includes a substrate body made of a metallic material that is magnesium or magnesium alloy, and a porous passivation layer which is disposed on the substrate body, and which is made of an oxide of the metallic material. The sealing layer is disposed on the porous passivation layer, and is made of a sealing material. The conductive layer is disposed on the sealing layer, and is made of an electrically conductive material. The coating layer covers the conductive layer, and includes an electrophoretic material and/or a metal. A method of making the composite structure is also disclosed.

### CROSS-REFERENCE TO RELATED APPLICATION

This application claims priority of Taiwanese Invention Patent Application No. 109133109, filed on Sep. 24, 2020.

### FIELD

The disclosure relates to a composite structure and a method of making the same.

### BACKGROUND

in order to fulfill the requirements of small size and light weight for a portable electronic device, light metals (such as titanium, magnesium, and aluminum) having a relatively high mechanical strength and a relatively low specific gravity are conventionally used as raw materials for manufacturing a casing of such portable electronic devices, among which magnesium alloy receives great interests due to its superior conductivity and anti-shock properties.

Since magnesium alloy is subjected to partial corrosion due to its high reactivity with oxygen-containing elements (such as water), a passivation layer is usually disposed on a substrate made of magnesium alloy to provide salt-fog resistance and to prevent contact with water. However, the porous property of the passivation layer might demolish the metallic appearance of the substrate. To refine the metallic appearance, a coating layer is formed on the passivation layer by virtue of electrophoretic deposition (ED) of a painting material or a metallic material.

Nevertheless, the porous and unevenness properties of the passivation layer result in poor adhesion to the coating layer, and the non-conductive property of the passivation layer also adversely affects the formation of the coating layer by electroplating or electrophoretic deposition.

Therefore, there is still a need to avoid corrosion of the highly-reactive magnesium alloy, and to improve the adherence between the coating layer and the passivation layer.

### SUMMARY

Therefore, an object of the disclosure is to provide a composite structure and a method of making the same that can alleviate at least one of the drawbacks of the prior art.

According to the disclosure, the composite structure comprises a passivated substrate which includes a substrate body and a porous passivation layer, a sealing layer, a conductive layer, and a coating layer.

The passivated substrate includes a substrate body made of a metallic material that is selected from the group consisting of magnesium and magnesium alloy, and a porous passivation layer disposed on the substrate body. The porous passivation layer is formed with a plurality of pores extending towards the substrate body, and is made of an oxide of the metallic material.

The sealing layer is disposed on the porous passivation layer opposite to the substrate body, and is made of a sealing material.

The conductive layer is disposed on the sealing layer opposite to the porous passivation layer, and is made of an electrically conductive material.

The coating layer covers the conductive layer opposite to the sealing layer, and includes one of an electrophoretic material, a metal, and a combination thereof.

According to the disclosure, the method includes the steps of:

providing a substrate which includes a substrate body made of a metallic material that is selected from the group consisting of magnesium and magnesium alloy,

subjecting the substrate to a passivation treatment in such a manner that a porous passivation layer is formed on the substrate body and that a plurality of pores are formed in the porous passivation layer to extend towards the substrate body, the porous passivation layer being made of an oxide of the metallic material of the substrate body;

applying a sealing material to the porous passivation layer, so as to forma sealing layer on the porous passivation layer;

forming a conductive layer on the sealing layer using an electrically conductive material; and

forming a coating layer on the conductive layer, in which the coating layer includes one of an electrophoretic material, a metal and a combination thereof.

### BRIEF DESCRIPTION OF THE DRAWINGS

Other features and advantages of the disclosure will become apparent in the following detailed description of the embodiment(s) with reference to the accompanying drawings, of which:

FIG. 1 is a schematic view illustrating an embodiment of a composite structure according to the disclosure;

FIG. 2 is a flow chart illustrating an embodiment of a method of making the composite structure according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

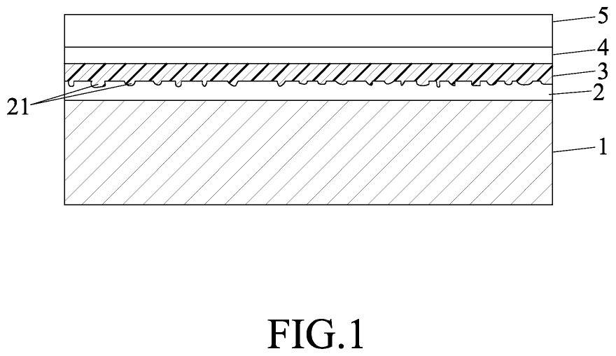

Referring to FIG. 1, an embodiment of a composite structure according to the disclosure includes a passivated substrate, a sealing layer 3, a conductive layer 4, and a coating layer 5.

The passivated substrate includes a substrate body 1 made of a metallic material, and a porous passivation layer 2 made of an oxide of the metallic material. The metallic material may be magnesium or magnesium alloy. In this embodiment, the substrate body 1 is made of magnesium alloy. Examples of the magnesium alloy may include, but are not limited to, AZ31B alloy, AZ91D alloy, and a combination thereof.

The porous passivation layer 2 is disposed on the substrate body 1, and is formed with a plurality of pores 21 extending towards the substrate body 1. The porous passivation layer 2 is capable of exhibiting salt-fog resistance and inhibiting corrosion by water. The porous passivation layer 2 may have a thickness that ranges from 1 μm to 10 μm. In certain embodiments, the thickness of the porous passivation layer 2 ranges from 4 μm to 8 μm. In other embodiments, the thickness of the passivation layer 2 ranges from 1 μm to 2 μm. When the porous passivation layer 2 is thinner, the metallic appearance of the substrate body 1 may be less affected thereby.

The sealing layer 3 is disposed on the porous passivation layer 2 opposite to the substrate body 1, and is made of a sealing material. The sealing material may include silicone resin. In this embodiment, the sealing layer 3 fills in at least a portion of pores 21, so as to smooth the porous passivation layer 2 of the passivated substrate, and to prevent acidic or basic solution from infiltrating into and corroding the substrate body 1 via the pores 21 during the subsequent process for forming the conductive layer 4 and the coating layer 5, thereby providing a protective function for the substrate body 1 of the passivated substrate. The sealing layer 3 may have a thickness that ranges from 0.5 μm to 3 μm.

The conductive layer 4 is disposed on the sealing layer 3 opposite to the porous passivation layer 2, and is made of an electrically conductive material. Examples of the electrically conductive material may include graphene, a nano carbon material, a metal, and combinations thereof. The conductive layer 4 may have a thickness that ranges from 0.5 μm to 3 μm. In this embodiment, the conductive layer 4 is made of graphene, which exhibits not only a good electrical conductivity but also a desired thermal conductivity.

The coating layer 5 covers the conductive layer 4 opposite to the sealing layer 3 to provide a smooth surface. The coating layer 5 may have a thickness that ranges from 10 μm to 30 μm. The coating layer 5 may include one of an electrophoretic material (such as an electrophoretic paint), a metal, and a combination thereof.

In this embodiment, a total thickness of the porous passivation layer 2, the sealing layer 3, the conductive layer 4 and the coating layer 5 is controlled within a range of 25 μm to 40 μm, so as to impart metallic appearance as well as to improve salt-fog resistance and heat dissipation properties to the composite structure of this disclosure.

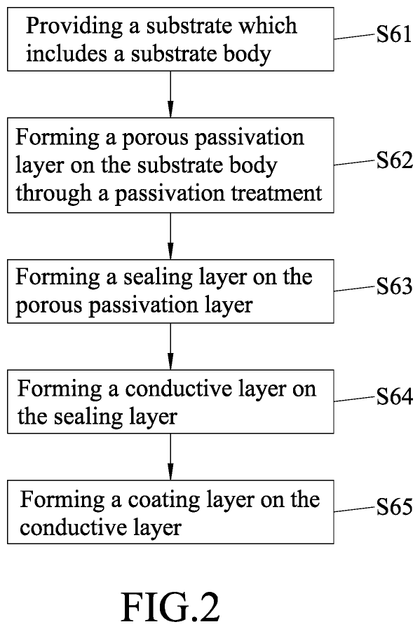

Referring to FIG. 2, an embodiment of a method of making the aforementioned composite structure according to the disclosure includes the following steps S61 to S65.

In step S61, a substrate which includes the substrate body 1 with a predetermined shape and thickness is provided by subjecting the metallic material to an injection molding process.

In this embodiment, the substrate is provided by an thixomolding process, in which the metallic material is processed by heating and bolt shearing simultaneously, and then the resultant semi-solid slurry was subjected to the injection molding process to produce the substrate. It should be noted that the manufacturing parameters and conditions for the injection molding process may vary depending on the metallic material to be used, and the adjustment and optimization thereof are within the expertise of those skilled in the art, and thus the details thereof are omitted herein for the sake of brevity. Besides, the structure (such as the thickness and shape) of the substrate body 1 is not limited specifically, and can be modified based on practical requirements.

In step S62, the substrate is subjected to a passivation treatment in such a manner that the porous passivation layer 2 made of an oxide of the metallic material is formed on the substrate body 1, and that a plurality of pores 21 are formed in the porous passivation layer 2 to extend towards the substrate body 1.

In this embodiment, the passivation treatment is conducted via micro-arc oxidation to form the porous passivation layer 2. Specifically, the substrate body 1 serving as an anode is immersed in an electrolyte solution containing silicate, and then a gradually increasing electric voltage is continuously applied to the electrolyte solution to generate continuous plasma discharging on a surface of the substrate body 1, so as to oxidize the metallic material of the substrate body, thereby forming the porous passivation layer 2 made of an oxide of the metallic material on the surface of the substrate body 1. The substrate body 1 and the porous passivation layer 2 cooperate to form the passivated substrate. Since the oxide of the metallic material exhibits a superior insulating property and good abrasive resistance, the porous passivation layer 2 is capable of improving the insulativity and abrasive resistance of the passivated substrate.

In step 63, the sealing material is applied to the porous passivation layer 2 via, e.g. a coating process (such as dip coating), so as to form a sealing layer 3 thereon. Specifically, in this embodiment, a solution containing silicone resin which is applied on the porous passivation layer 2, would flow into at least a portion of the pores 21. Then, a baking process is conducted under 120° C. to 150° C. to cure the silicone resin, thereby obtaining the sealing layer 3.

In step 64, the conductive layer 4 is formed on the sealing layer 3 using the electrically conductive material. Step 64 may be performed by a process selected from the group consisting of coating, chemical plating, electroplating, and combinations thereof.

In step 65, the coating layer 5 is formed on the conductive layer 4. Step 65 may be performed by a process selected from the group consisting of electrophoretic deposition, electroplating, and a combination thereof. Specifically, the electrophoretic material which may include a conductive substance or a charged colloidal solution (i.e., a suspension of colored or charged particles or colloidal material) is deposited on the conductive layer 4 by electrophoretic deposition, so as to form the coating layer 5. In this embodiment, the charged colloidal solution including charged and colored particles (i.e., dye, pigment or paint) is prepared, and then an electric voltage is applied to allow the charged and colored particles to migrate and deposit on a surface of the conductive layer 4 under the effect of the electric field, thereby forming the coating layer 5 with a smooth surface. It should be noted that, the materials and the parameters suitable for electrophoretic deposition and electroplating are within the expertise of those skilled in the art, and thus the details thereof are omitted herein for the sake of brevity.

Since the porous passivation layer 2 and the sealing layer 3 are not conductive and would not favor electrophoretic deposition or electroplating for forming the coating layer 5, the conductive layer 4 with electrical conductivity is therefore disposed on the sealing layer 3 to serve as a medium so as to assist in forming the coating layer 5 and in improving the adherence therebetween. In addition, the conductive layer 4 which also exhibits good thermal conductivity can provide an excellent heat dissipation efficiency to the composite structure according to this disclosure, which is thus suitable for use in manufacture of electronic devices.

In summary, by forming the sealing layer 3 to smooth the uneven surface of the porous passivation layer 2 of the passivated substrate, enhanced adhesion of the conductive layer 4 and the coating layer 5 to the passivated substrate can be achieved, so as to prevent separation of these layers from the passivated substrate. In addition, since the conductive layer 4 with good thermal and electrical conductivities is conducive to the formation of the coating layer 5 via electrophoretic deposition or electroplating, the appearance as well as the heat dissipation property of the composite structure of this disclosure can be improved.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiment, it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A composite structure, comprising:
a passivated substrate which includes a substrate body made of a metallic material that is selected from the group consisting of magnesium and magnesium alloy, and a porous passivation layer disposed on said substrate body, said porous passivation layer being formed with a plurality of pores extending towards said substrate body, and being made of an oxide of said metallic material;
a sealing layer which is disposed on said porous passivation layer opposite to said substrate body, and which is made of a sealing material;
a conductive layer which is disposed on said sealing layer opposite to said porous passivation layer, and which is made of an electrically conductive material;
a coating layer which covers said conductive layer opposite to said sealing layer, and which includes one of an electrophoretic material, a metal, and a combination thereof.

2. The composite structure according to claim 1, wherein said porous passivation layer has a thickness that ranges from 4 μm to 8 μm.

3. The composite structure according to claim 1, wherein said sealing layer has a thickness that ranges from 0.5 μm to 3 μm.

4. The composite structure according to claim 1, wherein said conductive layer has a thickness that ranges from 0.5 μm to 3 μm.

5. The composite structure according to claim 1, wherein said coating layer has a thickness that ranges from 10 μm to 30 μm.

6. The composite structure according to claim 1, wherein a total thickness of said porous passivation layer, said sealing layer, said conductive layer and said coating layer is within a range of 25 μm to 40 μm.

7. The composite structure according to claim 1, wherein said electrically conductive material includes at least one selected from the group consisting of graphene, a nano carbon material, and a metal.

8. The composite structure according to claim 1, wherein said sealing material includes silicone resin, and said sealing layer fills in at least a portion of said pores.

9. A method of making a composite structure, comprising the steps of:
providing a substrate which includes a substrate body made of a metallic material that is selected from the group consisting of magnesium and magnesium alloy;
subjecting the substrate to a passivation treatment in such a manner that a porous passivation layer is formed on the substrate body and that a plurality of pores are formed in the porous passivation layer to extend towards the substrate body, the porous passivation layer being made of an oxide of the metallic material of the substrate body;
applying a sealing material to the porous passivation layer, so as to form a sealing layer on the porous passivation layer;
forming a conductive layer on the sealing layer using an electrically conductive material; and
forming a coating layer on the conductive layer, the coating layer including one of an electrophoretic material, a metal and a combination thereof.

10. The method according to claim 9, wherein the step of providing the substrate is performed by a thixomolding process.

11. The method according to claim 9, wherein the porous passivation layer is formed by micro-arc oxidation.

12. The method according to claim 9, wherein the step of forming the conductive layer is performed by a process selected from the group consisting of coating, chemical plating, electroplating, and combinations thereof.

13. The method according to claim 9, wherein the step of forming the coating layer is performed by a process selected from the group consisting of electrophoretic deposition, electroplating, and a combination thereof.

14. The method according to claim 9, wherein the porous passivation layer formed has a thickness ranging from 4 μm to 8 μm.

15. The method according to claim 9, wherein the sealing layer formed has a thickness ranging from 0.5 μm to 3 μm.

16. The method according to claim 9, wherein the conductive layer formed has a thickness ranging from 0.5 μm to 3 μm.

17. The method according to claim 9, wherein the coating layer formed has a thickness ranging from 10 μm to 30 μm.

18. The method according to claim 9, wherein a total thickness of the porous passivation layer, the sealing layer, the conductive layer and the coating layer is within a range of 25 μm to 40 μm.

19. The method according to claim 9, wherein the electrically conductive material includes at least one selected from the group consisting of graphene, a nano carbon material, and a metal.

20. The method according to claim 9, wherein the sealing material includes silicone resin, and the sealing layer fills in at least a portion of the pores of the porous passivation layer.
